(19) United States
(12) Patent Application Publication
(10) Pub. No.: US 2021/0061644 A1
(43) Pub. Date: Mar. 4, 2021

(54) MEMS INKJET PRINTHEAD HAVING RECIRCULATING INK PATHWAY

(71) Applicant: MEMJET TECHNOLOGY LIMITED, Dublin (IE)

(72) Inventor: MICHAEL HUDSON, North Ryde (AU)

(21) Appl. No.: 17/002,694

(22) Filed: Aug. 25, 2020

Related U.S. Application Data
(60) Provisional application No. 62/892,436, filed on Aug. 27, 2019.

(51) Int. Cl. B81B 7/00; B41J 2/185

(52) U.S. Cl. CPC B81B 7/0061; B41J 2/185

(57) ABSTRACT

A MEMS printhead including: a plurality of nozzle chambers arranged in a plurality of nozzle rows, each nozzle chamber having: a nozzle opening for ejection of ink, an inlet channel extending parallel with a direction of droplet ejection and an outlet channel extending perpendicular to the inlet channel; an ink delivery channel extending parallel with the nozzle rows, the ink delivery channel supplying ink to a plurality of inlet channels; a plurality of ink collection channels extending across the nozzle rows, each ink collection channel collecting ink from a set of outlet channels; and an ink receiving channel extending parallel with the nozzle rows, the ink receiving channel receiving ink from the ink collection channels.

### Cross Reference to Related Applications

This application claims priority to and the benefit of U.S. Provisional Patent Application No. 62/892,436, entitled MEMS INKJET PRINTHEAD HAVING RECIRCULATING INK PATHWAY, filed on Aug. 27, 2019, the disclosure of which is incorporated herein by reference in its entirety for all purposes.

### Field of the Invention

This invention relates to a MEMS inkjet printhead having a recirculating ink pathway. It has been developed primarily to minimize nozzle dehydration, improve temperature control, facilitate bubble management and improve ink stability in such printheads.

### BACKGROUND OF THE INVENTION

The Applicant has developed a range of Memjet® inkjet printers as described in, for example, WO2011/143700, WO2011/143699 and WO2009/089567, the contents of which are herein incorporated by reference. Memjet® printers employ a stationary pagewidth printhead in combination with a feed mechanism which feeds print media past the printhead in a single pass. Memjet® printers therefore provide much higher printing speeds than conventional scanning inkjet printers.

An inkjet printhead is comprised of a plurality (typically thousands) of individual inkjet nozzle devices, each supplied with ink. Each inkjet nozzle device typically comprises a nozzle chamber having a nozzle aperture and an actuator for ejecting ink through the nozzle aperture. The design space for inkjet nozzle devices is vast and a plethora of different nozzle devices have been described in the patent literature, including different types of actuators and different device configurations. For example, MEMS inkjet nozzle devices may achieve droplet ejection via a thermal bubble-forming actuator as described in U.S. Pat. No. 9,044,945 (the contents of which are incorporated herein by reference), via a thermal bend actuator as described in U.S. Pat. No. 7,984,973 (the contents of which are incorporated herein by reference), or via piezo actuation as readily understood by those skilled in the art.

With the miniaturization of inkjet nozzle devices, particularly those fabricated on a micron scale via MEMS fabrication processes, a number of problems arise for the operation of such devices. For example, ink dehydration via evaporation through nozzles can result in a viscous plug of ink trapped in the nozzle (a phenomenon known in the art as ‘decap’); bubbles in the ink may block ink flow through capillary channels in the printhead resulting in depriming; ink temperature may vary across nozzle chambers in the printhead resulting in variations in ink viscosity and consequent variations in droplet size; and non-soluble ink components (e.g. pigments) may flocculate and cause sedimentation within nozzle chambers. To some extent, these problems may be mitigated through the design or operation of printheads. For example, dehydration may be addressed by providing wide ink delivery channels in proximity to nozzle chambers, as well as inter-page spitting and/or keep-wet spitting (as described in, for example, U.S. Pat. No. 9,545,787, the contents of which are incorporated herein by reference); bubbles may be addressed via printhead design (as described in, for example, U.S. Pat. No. 10,035,357, the contents of which are incorporated herein by reference); temperature variations may be addressed via non-ejecting heating pulses; and sedimentation may be addressed via ink design.

Notwithstanding the above-mentioned measures to address certain problems in MEMS inkjet printheads, it is known that ink circulation is highly effective in addressing such problems. However, ink circulation through MEMS structures adds significantly to printhead complexity as well ink delivery systems.

U.S. Pat. No. 9,511,598 (assigned to Fujifilm Dimatix, Inc) describes a piezo inkjet printhead having an ink recirculation pathway connected to each nozzle in the form of a V-shaped channel, which directs non-ejected ink to a return manifold.

U.S. Pat. No. 9,090,084 (assigned to Hewlett-Packard Development Company, L.P.) describes a thermal inkjet printhead whereby each nozzle chamber has a respective ink recirculation pathway in a plane of the nozzle chamber. Ink is supplied from a wide ink channel and recirculated back to the same ink channel via the nozzle chamber.

U.S. Pat. No. 8,517,518 (assigned to Canon Kabushiki Kaisha) describes a thermal printhead comprising nozzles chambers having inlet and outlet channels extending from a floor of each chamber for recirculation of ink. The inlet channel is connected to a respective ink delivery channel and the outlet channel is connected to a respective ink receiving channel at a lower hydrostatic pressure than the ink delivery channel.

It would be desirable to provide an alternative MEMS printhead having a recirculating ink pathway. It would be particularly desirable to provide a MEMS printhead having a minimal number of ink receiving channels, whilst maximizing ink available for delivery to nozzle chambers.

### SUMMARY OF THE INVENTION

In a first aspect, there is provided a MEMS printhead comprising:

a plurality of nozzle chambers arranged in a plurality of nozzle rows, each nozzle chamber having: a nozzle opening for ejection of ink, an inlet channel extending parallel with a direction of droplet ejection and an outlet channel extending perpendicular to the inlet channel;

an ink delivery channel extending parallel with the nozzle rows, the ink delivery channel supplying ink to a plurality of inlet channels;
a plurality of ink collection channels extending across the nozzle rows, each ink collection channel collecting ink from a set of outlet channels; and
an ink receiving channel extending parallel with the nozzle rows, the ink receiving channel receiving ink from the ink collection channels.

The printhead according to the first aspect advantageously enables ink to be recirculated through the nozzle chambers into backside MEMS channels via a common ink collection channel, which collects ink from a set of nozzle chambers across a plurality of nozzle rows. Thus, the available space available for the ink delivery channel(s) is maximized and the recirculated ink may be collected from longitudinal edge regions of the printhead, which are usually not used for printhead fluidics.

The printhead according to the first aspect is typically a MEMS printhead chip in the form of a thin slither of silicon having MEMS inkjet devices fabricated on one side. A plurality of printhead chips may be arranged (e.g. a staggered or butting arrangement) to form a pagewide printhead, as is known in the art.

Preferably, the ink collection channels extend through a space defined between neighboring pairs of nozzle chambers within each nozzle row. Therefore, recirculated ink is able to flow across the printhead between nozzle chambers.

Preferably, the ink collection channels extend across a set of nozzle rows. For example, a set of nozzle row may contain 2, 3, 4, 5, 6, 7, 8, 9 or 10 nozzle rows. Typically, the ink collection channels have a width in the range of 5 to 30 microns.

Preferably, the ink collection channels and/or outlet channels are coplanar with the nozzle chambers. Typically, the ink collection channels and/or outlet channels are formed at the same time as the nozzle chambers during frontside MEMS processing. Accordingly, a height of the ink collection channels and/or outlet channels corresponds to a height of the nozzle chambers. For example, the height of the nozzle chambers, the outlet channels and the ink collection channels may be in the range of 4 to 20 microns or 6 to 12 microns. A suitable MEMS fabrication process for forming nozzle chambers (and coplanar channels) is described in, for example, U.S. Pat. No. 7,819,503, the contents of which are herein incorporated by reference.

Preferably, ink delivery channel is coplanar with the ink receiving channel Typically, the ink delivery channel(s) are formed at the same time as the ink receiving channel(s) via deep reactive ion etching (DRIE), such as a Bosch etch.

Preferably, the ink delivery channel and the ink receiving channel are defined in a backside surface of the printhead opposite the nozzle chambers.

Preferably, the ink receiving channel is offset from the nozzle rows.

Preferably, the ink receiving channel is positioned towards a longitudinal edge of the printhead such that ink is recirculated towards the longitudinal edge of the printhead. As foreshadowed above, this configuration maximizes the space available for the ink delivery channels.

Preferably, a pair of ink receiving channels flank one or more ink delivery channels. Flanking ink receiving channels may be used either in a monochrome printhead or a color printhead (e.g. two-color printhead).

Preferably, the ink delivery channel is aligned with one or more nozzle rows.

Preferably, at least one outlet channel has a different dimension (e.g. width dimension and/or length dimension) than at least one other outlet channel Adjusting the dimensions of the outlet channels enables hydrostatic pressures and circulating ink flow rates to be tuned (or equalized) in the ink pathway.

For example, a first outlet channel relatively distal from the ink receiving channel may be wider and/or shorter than a second outlet channel relatively proximal to the ink receiving channel, the first and second outlet channels feeding ink to the ink receiving channel via a common ink collection channel In one example, a ratio of the width of the first outlet channel (W₁) to the width of the second outlet channel (W₂) may be in the range of 5:1 to 1.1:1. In another example, the ratio of the length of the first outlet channel (L₁) to the length of the second outlet channel (L₂) may be in the range of 1:1.1 to 1:5.

In printheads having a plurality of ink receiving channels, the ink receiving channel referred to above is the one nearest to the first and second outlet channels.

Typically, the outlet channels have a width in the range of 2 to 10 microns (e.g. 2 to 5 microns) and a length in the range of 10 to 100 microns.

In one embodiment, the outlet channels extend from the nozzle chambers parallel to nozzle rows. In another embodiment, the outlet channels extend from the nozzle chambers perpendicular to nozzle rows. In another embodiment, the outlet channels extend from the nozzle chambers obliquely with respect to nozzle rows.

Preferably, a number of ink delivery channels is greater than a number of ink receiving channels. Preferably, the ink delivery channel is wider than the ink receiving channel Preferably, the ink delivery channel contains ink at a relatively higher hydrostatic pressure than ink contained in the ink receiving channel A suitable recirculating ink delivery system for providing relatively higher and lower hydrostatic pressures at printhead inlet and outlet ports, respectively, is described in U.S. Pat. No. 10,252,540, the contents of which are incorporated herein by reference.

Preferably, each nozzle chamber has its respective outlet channel positioned relatively nearer its respective nozzle opening than its respective inlet channel.

As used herein, the term “ink” refers to any ejectable fluid and may include, for example, conventional CMYK inks (e.g. pigment and dye-based inks), infrared inks, UV-curable inks, fixatives, 3D printing fluids, polymers, biological fluids etc.

### BRIEF DESCRIPTION OF THE DRAWINGS

Embodiments of the present invention will now be described by way of example only with reference to the accompanying drawings, in which:

FIG. 1 is a schematic plan view of a portion of a printhead according to a first embodiment;

FIG. 2 is a cross-section along line A-A of the printhead shown in FIG. 1;

FIG. 3 is a schematic plan view of a portion of a printhead according to a second embodiment;

FIG. 4 is a cross-section along line A-A of the printhead shown in FIG. 3;

FIG. 5 is a schematic plan view of a portion of a printhead according to a third embodiment;

FIG. 6 is a schematic plan view of a portion of a printhead according to a fourth embodiment; and

FIG. 7 is a schematic plan view of a portion of a printhead according to a fifth embodiment.

### DETAILED DESCRIPTION OF THE INVENTION

In the embodiments described below, like reference numerals have been used to describe like features, where appropriate.

### First Embodiment

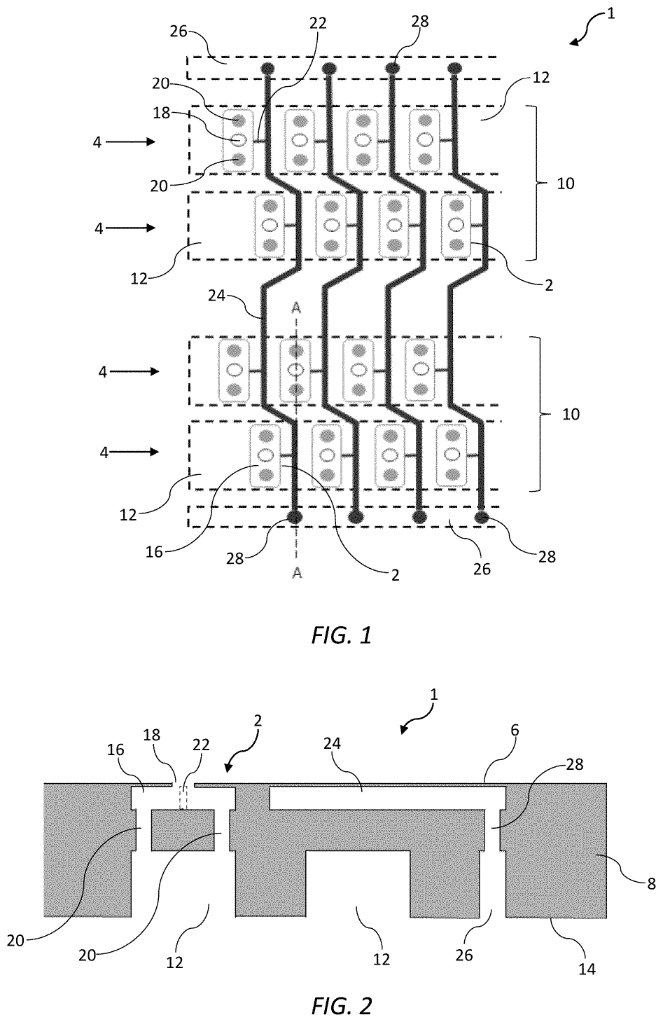

Referring to FIGS. 1 and 2, there is shown a first embodiment of part of a printhead 1 according to the present invention. The printhead 1 may be in the form of, for example, an elongate printhead chip fabricated using MEMS fabrication processes from a silicon wafer. The printhead 1 of the first embodiment is a monochrome printhead comprising a plurality of inkjet nozzle devices 2 arranged in nozzle rows 4 on a frontside 6 of a silicon substrate 8 (e.g. a monolayered or multilayered silicon substrate). Although only a portion of each nozzle row 4 is shown in FIG. 1, it will be appreciated that each nozzle row may contain hundreds or thousands of inkjet nozzles devices 2 arranged along a length of the printhead 1.

The printhead 1 nominally has two print channels 10, each print channel containing a pair of nozzle rows 4 (for printing ‘odd’ and ‘even’ dots in one line of print) supplied with ink from a respective ink delivery channel 12, which is defined in a backside 14 of the silicon substrate 8 and extends parallel with the nozzle rows 4. However, it will of course be appreciated that the printhead 1 may comprises a greater or fewer number of nozzle rows 4. For example, the printhead may comprise five print channels 10 and ten nozzles rows 4.

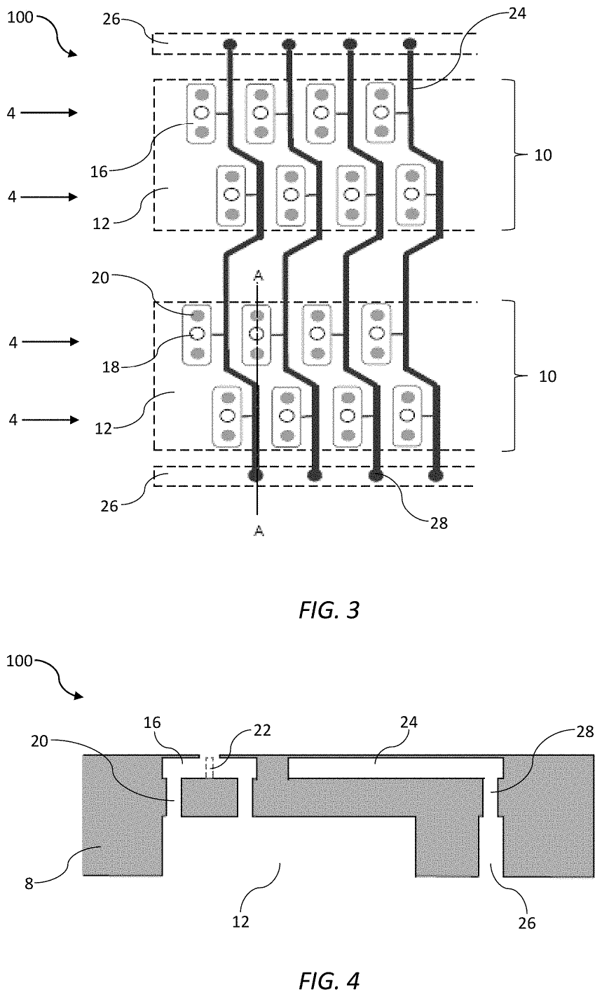

In the first embodiment shown in FIG. 1, there are four ink delivery channels 12 corresponding to one ink delivery channel for each nozzle row 4, although in alternative embodiments a pair of nozzle rows contained in one print channel 10 may share a common ink delivery channel (see FIGS. 3 and 4).

The inkjet nozzle devices 2 may eject ink using any suitable means using, for example, a thermal bubble-forming actuator as described in U.S. Pat. No. 9,044,945; a thermal bend actuator as described in U.S. Pat. No. 7,984,973; or a piezo actuator as readily understood by those skilled in the art. For the purposes of clarity, the inkjet nozzle devices 2 in the Figures are shown schematically as generic devices without a specific type of inkjet actuator.

Still referring to FIGS. 1 and 2, each inkjet nozzle device 2 comprises a nozzle chamber 16 having a nozzle opening 18 for ink ejection, an inlet channel 20 (e.g. a single inlet channel or a pair of inlet channels as shown in FIGS. 1 and 2) and an outlet channel 22. The inlet channel(s) 20 extends from the nozzle chamber 16 through the silicon substrate 8 parallel with a direction of droplet ejection, while the outlet channel 22 extends from the nozzle chamber perpendicular to the inlet channel (and parallel to the nozzle rows 4 in the first embodiment shown in FIG. 1).

A plurality of ink collection channels 24 (or ‘buses’) extend across the frontside of the printhead 1 in a plane of the nozzle chambers 16. Each ink collection channel 24 is connected to a set of nozzle chambers 16 (e.g. 2 to 10 nozzle chambers) via respective outlet channels 22. In the first embodiment shown in FIG. 1, each ink collection channel 24 is connected to four outlet channels 22, passing between neighbouring nozzle chambers 16 in each of the four nozzle rows 4. However, it will be appreciated that in printheads with a greater number of nozzle rows 4, the ink collection channel 24 may be connected to a greater number of outlet channels 22.

The ink collection channels 24 follow a meandering path across the printhead 1 by virtue of the offset configuration of the ‘odd’ and ‘even’ nozzle rows. Each ink collection channel 24 terminates towards opposite longitudinal sides of the printhead 1 and feeds ink to a pair of backside ink receiving channels 26, extending parallel with the ink delivery channels 20, via respective drain channels 28. The drain channels 28 are parallel and typically coextensive with the inlet channels 20 of the nozzle chambers 16.

In use, a fluidic circuit is formed between the ink receiving channel 26 and the ink delivery channel 12 so as to allow recirculation of ink through the printhead 1 via the nozzle chambers 16. In this way, ink in each nozzle chamber 16 may be continuously refreshed even when a particular inkjet nozzle device 2 is not being used for printing. As foreshadowed above, such an arrangement mitigates potential problems, such as nozzle dehydration, bubble management, thermal regulation and ink stability.

The ink receiving channel 26 is typically held at a lower hydrostatic pressure than the ink delivery channel 12 (e.g. by means of pump(s) in an ink delivery system, not shown) such that ink flows from the ink delivery channel, through the nozzles chambers 16 and into the ink receiving channel via the ink collection channels 24. In some embodiments, the inkjet nozzle devices 2 may be actuated using non-ejecting pulses so as to circulate ink through the various MEMS channels without ejecting ink from the printhead 1. Non-ejecting pulses may be employed in any type of inkjet actuator, including thermal bubble-forming actuators, thermal bend actuators and piezo actuators.

Advantageously, the dimensions of the ink delivery channels 12 are maximized so as to maximize a reservoir of ink available to each nozzle chamber 16 for printing. The ink receiving channels 26 and ink collection channels 24 do not have the same requirements as the ink delivery channels and can therefore have relatively smaller dimensions than the ink delivery channels. Typically, the relative widths of the various MEMS channels are in the order: ink delivery channel 12>ink receiving channel 26>ink collection channel 24.

For optimal droplet ejection from all inkjet nozzle devices 2 in the printhead 1, it is preferable for each nozzle chamber 16 to contain ink at the same hydrostatic pressure. Since the nozzle chambers 16 are connected in series via a common ink collection channel 24, and due to the flow resistances through the relatively narrow ink collection channels, the nozzle chambers furthest from the ink receiving channel 26 will not experience the same hydrostatic pressure as those closest to the ink receiving channel. In order to compensate for such pressure differences, the outlet channels 22 for nozzle chambers 16 furthest from a corresponding ink receiving channel 26 may be wider than outlet channels for nozzle chambers nearest the corresponding ink receiving channel Thus, the flow resistance between each nozzle chamber 16 and the ink receiving channel 26 may be equalized, thereby equalizing the hydrostatic pressure of ink contained in each nozzle chamber of the printhead and equalizing ink flow rates through each nozzle chamber.

### Second Embodiment

FIGS. 3 and 4 show a printhead 100 according to a second embodiment. The printhead 100 is identical in every respect to the printhead 1 according to the first embodiment, except that pairs of nozzle rows 4 (‘odd’ and ‘even’ nozzle rows) corresponding to each print channel 10 share a common ink delivery channel 12. This arrangement maximizes further a reservoir of ink available for each nozzle chamber 16.

### Third Embodiment

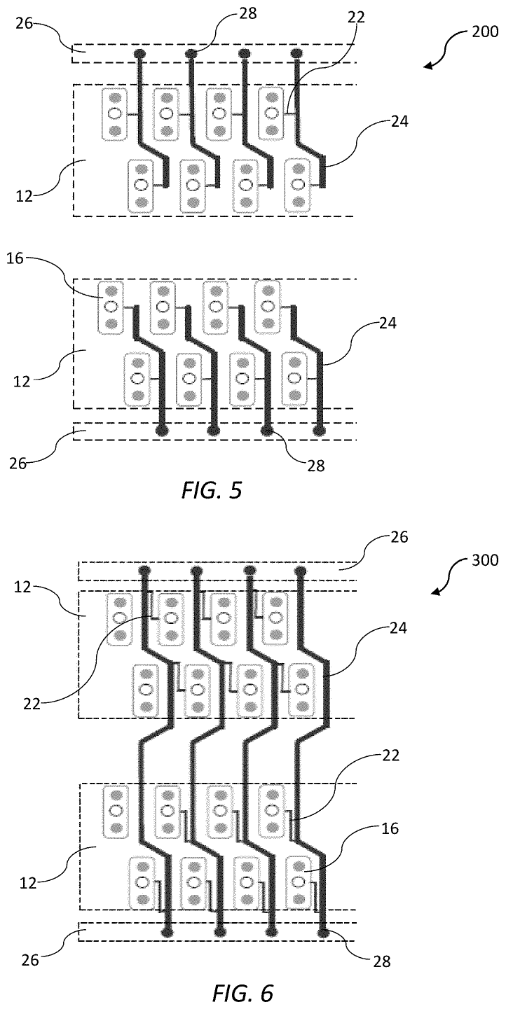

FIG. 5 shows a two-color printhead 200 according to a third embodiment. The printhead 200 is similar to the printhead 100, except each ink delivery channel 12 is supplied with a different colored ink and each ink collection channel 24 serves only one print channel 10 (i.e. one pair of nozzle rows 4 receiving ink from a common ink delivery channel 12). The ink collection channels 24 feed ink towards opposite sides of the printhead 200 into a respective ink receiving channels 26.

### Fourth Embodiment

FIG. 6 shows a monochrome printhead 300 according to a fourth embodiment. The printhead 300 is identical in every respect to the printhead 1 according to the first embodiment, except that the outlet channels 22 between the nozzle chambers 16 and the ink collection channels 24 are lengthened. In the printhead 300, the lengthened outlet channels 22 may advantageously provide greater control in equalizing hydrostatic pressures and circulating ink flow rates. For example, the relative lengths of the outlet channels 22 may be used to vary flow resistances, either as an alternative to varying the widths of the outlet channels or in addition to varying the widths of the outlet channels.

### Fifth Embodiment

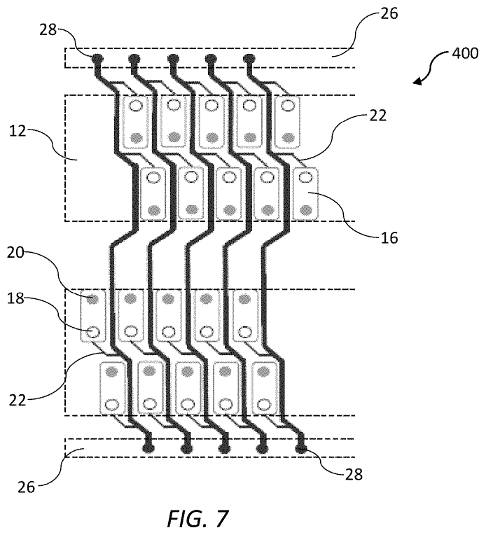

FIG. 7 shows a monochrome printhead 400 according to a fifth embodiment. In this embodiment, the outlet channels 22 extend obliquely from one end of each nozzle chamber 16. This arrangement contrasts with the printhead 100 according to the first embodiment in which the outlet channels 22 extend laterally from a side of each nozzle chamber 16. The printhead 400 according to the fifth embodiment advantageously minimizes a required space between neighboring nozzle chambers 16, since this space accommodates only the ink collection channel 24 and not the outlet channel 22. Thus, the printhead 400 is advantageous for reducing nozzle pitch. Additionally, the inkjet nozzle devices 2 in the printhead 400 have only one inlet channel 20 with a nozzle opening 18 at an opposite end of the elongate nozzle chamber 16 and the outlet channel 22 positioned adjacent the nozzle opening.

Combinations of the various embodiments described herein will also be readily apparent to the person skilled in the art. For example, any of the outlet channel configurations described in connection with the fourth and fifth embodiments may be used in a two-color printhead.

Furthermore, it will appreciated that printheads for printing three or more colors may employ a similar recirculating design as those described above by positioning an ink receiving channel 26 between each print channel 10.

It will, of course, be appreciated that the present invention has been described by way of example only and that modifications of detail may be made within the scope of the invention, which is defined in the accompanying claims.

1. A MEMS printhead comprising:
a plurality of nozzle chambers arranged in a plurality of nozzle rows, each nozzle chamber having: a nozzle opening for ejection of ink, an inlet channel extending parallel with a direction of droplet ejection and an outlet channel extending perpendicular to the inlet channel;
an ink delivery channel extending parallel with the nozzle rows, the ink delivery channel supplying ink to a plurality of inlet channels;
a plurality of ink collection channels extending across the nozzle rows, each ink collection channel collecting ink from a set of outlet channels; and
an ink receiving channel extending parallel with the nozzle rows, the ink receiving channel receiving ink from the ink collection channels.

2. The printhead of claim 1, wherein each ink collection channel extends through a space defined between neighboring pairs of nozzle chambers within each nozzle row.

3. The printhead of claim 1, wherein the ink collection channels extend across a set of nozzle rows.

4. The printhead of claim 1, wherein the ink collection channels are coplanar with the nozzle chambers.

5. The printhead of claim 1, wherein the ink delivery channel is coplanar with the ink receiving channel.

6. The printhead of claim 5, wherein the ink delivery channel and the ink receiving channel are defined in a backside surface of the printhead opposite the nozzle chambers.

7. The printhead of claim 1, wherein the ink receiving channel is offset from the nozzle rows.

8. The printhead of claim 1, wherein the ink receiving channel is positioned towards a longitudinal edge region of the printhead such that recirculated ink flow from the nozzle chambers towards the longitudinal edge region of the printhead.

10. The printhead of claim 1, wherein a pair of ink receiving channels flank one or more ink delivery channels.

11. The printhead of claim 1, wherein the ink delivery channel is aligned with one or more nozzle rows.

12. The printhead of claim 1, wherein at least one outlet channel has a different dimension than at least one other outlet channel

13. The printhead of claim 10, wherein a first outlet channel relatively distal from the ink receiving channel is wider and/or shorter than a second outlet channel relatively proximal to the ink receiving channel, the first and second outlet channels feeding ink to the ink receiving channel via a common ink collection channel

14. The printhead of claim 1, wherein the outlet channels extend parallel to nozzle rows, perpendicular to nozzle rows or obliquely with respect to nozzle rows.

15. The printhead of claim 1, wherein a number of ink delivery channels is greater than a number of ink receiving channels.

16. The printhead of claim 1, wherein the ink delivery channel is wider than the ink receiving channel.

17. The printhead of claim 1, wherein the ink delivery channel contains ink at a relatively higher hydrostatic pressure than ink contained in the ink receiving channel

18. The printhead of claim 1, wherein each nozzle chamber has its respective outlet channel positioned relatively nearer its respective nozzle opening than its respective inlet channel.
